(19) United States
(12) Patent Application Publication
(10) Pub. No.: US 2018/0076572 A1
(43) Pub. Date: Mar. 15, 2018

(54) GROUNDING STRUCTURE FOR SHIELD WIRES

(71) Applicant: Sumitomo Wiring Systems, Ltd., Yokkaichi (JP)

(72) Inventors: Hirokazu NAKAI, Yokkaichi (JP); Yuki OOHIRA, Yokkaichi (JP)

(21) Appl. No.: 15/665,775

(22) Filed: Aug. 1, 2017

(30) Foreign Application Priority Data
Sep. 15, 2016 (JP) 2016-180528

(51) Int. Cl. H01R 13/648; H01R 13/658; H01R 9/03; H05K 9/00

(52) U.S. Cl. CPC H01R 13/648; H05K 9/0098; H01R 9/034; H01R 13/65802

(57) ABSTRACT

Drain portions are formed by extracting portions of braided members of shield wires to the outside, one of the drain portions is used as a main drain portion, and a ground terminal to be connected to a ground point is attached to the leading end thereof. End portions on one side of relay wires are respectively connected to the remaining drain portions, and the other end portions of the relay wires are collectively connected to the ground terminal.

### CROSS REFERENCE TO RELATED APPLICATIONS

This application claims the priority of Japanese patent application JP2016-180528 filed on Sep. 15, 2016, the entire contents of which are incorporated herein.

### TECHNICAL FIELD

The present invention relates to a grounding structure for shield wires.

### BACKGROUND ART

In a wire harness routed in an automobile, it is common to use shield wires at locations at which blocking of noise in particular is required. In many forms of shield wires, a wire (a signal wire, etc.) is surrounded by a braided wire, for example. A braided wire in a shield wire is connected to ground, but grounding multiple shield wires separately is problematic in that grounding points increase in number, and the like. As a countermeasure against this, there is known to be a technique such as that disclosed in JP 2005-93198A below, in which multiple shield wires are grounded together as a group.

Intermediate portions of the shield wires are stripped so as to expose the braided wires inside, and in this state, the shield wires are bundled with the positions of the exposed portions aligned. Then, the terminal portion of a ground wire is overlaid on the exposed portions and is fixed by being fastened with a cable tie having an inner circumferential surface that is a conducting layer.

JP 2005-93198A is an example of related art.

With the above-described technique, it is required that the braided wires of the three shield wires are reliably in contact with each other and that the terminal portion of the ground wire is reliably in contact with one braided wire, but with the configuration of being fastened with the cable tie, the contact state of the braided wires is particularly unstable. For this reason, there is a risk that grounding will become unstable due to an increase in contact resistance.

### SUMMARY

The present design was achieved in light of the above-described circumstances, and an object thereof is to provide a grounding structure for shield wires according to which grounding can be stabilized.

A grounding structure for shield wires according to the present design is a grounding structure for shield wires, for collectively grounding a plurality of shield wires in which wires are surrounded by shield members, wherein drain portions are formed by extracting portions of the shield members of the shield wires to the outside, one of the drain portions is used as a main drain portion, and a ground terminal to be connected to a ground point is attached to a leading end of the main drain portion, and ends on one side of relay wires are connected to the respective remaining drain portions, and the other ends of the relay wires are connected collectively to the ground terminal.

With the present design, one of the drain portions extracted from the shield members of the multiple shield wires is selected as the main drain portion and the ground terminal is connected to the leading end thereof. The other drain portions are connected to the ground terminal as a group via the relay wires, and therefore compared to the case of grouping the multiple drain portions together, it is easier to perform grouping into a ground point and it is easier to perform a connection task at a ground point. Also, since the drain portions of the remaining shield wires are connected individually to the relay wires, grounding can be performed more stably in comparison to a method in which shield portions are brought into contact with each other by being tied together as with the conventional technique.

### BRIEF DESCRIPTION OF THE DRAWINGS

FIG. 1 is an overview showing a state in which three shield wires are routed in a vehicle.

FIG. 2 is a diagram showing a grounding structure according to an embodiment.

FIG. 3 is a cross-sectional view taken along line A-A in FIG. 2.

FIG. 4 is a cross-sectional view taken along line B-B in FIG. 2.

FIG. 5 is a cross-sectional view taken along line C-C in FIG. 2.

### EMBODIMENTS

Preferred embodiments will be described hereinafter.

A grounding structure for shield wires may be such that the remaining drain portions and the relay wires are respectively connected by being jointly fastened to barrel portions provided on joint terminals.

According to the above-described configuration, since the remaining drain portions and the relay wires are not directly connected but are connected by being jointly fastened to the barrel portions of the joint terminals, the connection task is easier.

Also, it is preferable that the shield members are braided wires obtained by braiding multiple metal element wires, the ground terminal is formed by including a wire barrel having a pair of barrel pieces and a fastening portion that is to be fixed to the ground point, and the wire barrel is crimped in a state in which the relay wires are arranged on a bottom surface side thereof and the main drain portion is arranged on a leading end side of the barrel pieces.

With this kind of configuration, the main drain portion is formed into a portion of the braided wire, or in other words, into an approximate band shape, and the core wires of the relay wires are relatively small in diameter. When different types are crimped together using the wire barrel of the ground terminal, if the relay wires are arranged on the bottom surface side and the braided wires are arranged on the leading end side of the barrel piece, the crimping force from the barrel piece can be made to act on the relay wires due to becoming a surface pressure from the braided main ground wire, and therefore the crimped state is stable, which results in contributing to a decrease in electrical resistance as well.

Next, a specific embodiment of the grounding structure for shield wires according to the present design will be described with reference to the drawings.

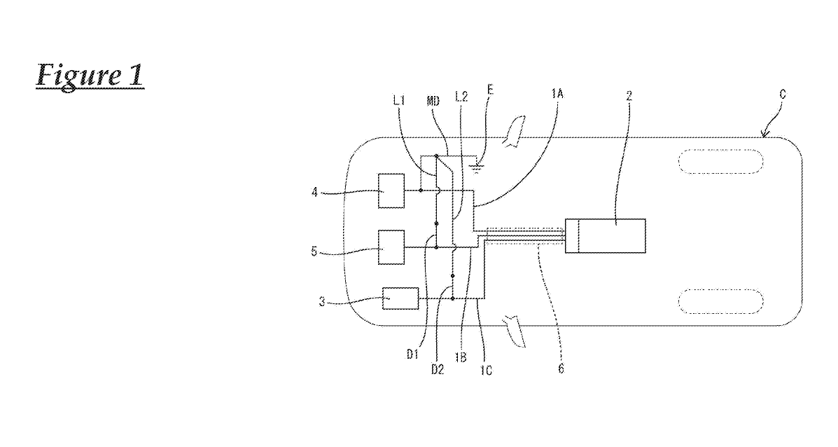

FIG. 1 shows a state in which three shield wires 1A, 1B, and 1C are routed in a hybrid vehicle C. A high-voltage battery 2 is arranged in the center of the vehicle, and devices such as an electric compressor 3 for air conditioning, a motor 4, and a low-voltage battery 5 are installed in the engine room. FIG. 1 schematically shows a state in which the high-voltage battery 2 and these devices are connected by the shield wires 1A, 1B, and 1C.

As shown in FIG. 1, intermediate portions of the shield wires 1A, 1B, and 1C are bundled into a group of three and are inserted into a shield pipe 6 made of metal (e.g., a pipe made of aluminum). The shield pipe 6 is laid underneath the floor of the vehicle. The shield wires 1A, 1B, and 1C penetrate through the vehicle front end side of the shield pipe 6, are introduced into the engine room thereafter, and are respectively connected to corresponding devices.

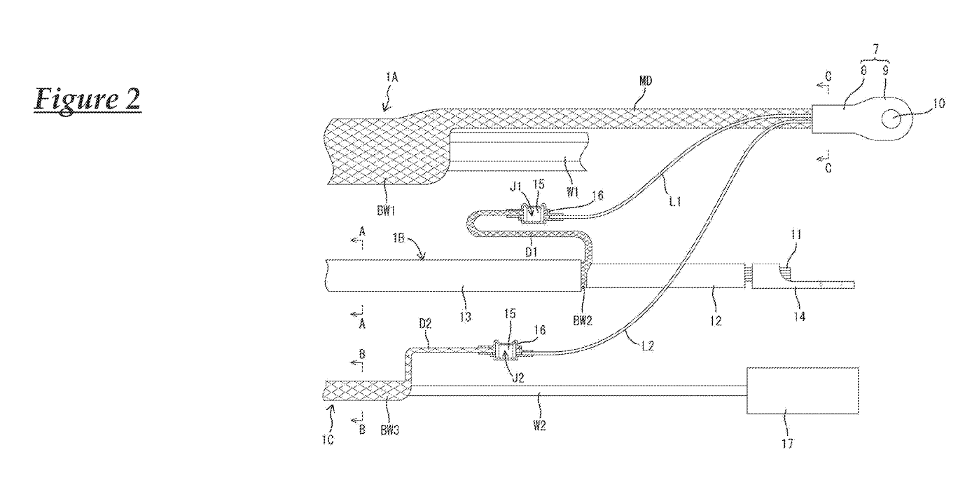

Among the shield wires, the shield wire connecting the high-voltage battery 2 and the motor 4 (hereinafter referred to as “first shield wire 1A”) has a form in which three wires W1 are collectively surrounded by a braided member BW1 (braided wire), although this is not illustrated in detail. The braided member BW1 is formed by braiding many metal element wires in a cylindrical shape. As shown in FIG. 2, at the end portion on the motor 4 side of the first shield wire 1A, a portion in the circumferential direction of the braided member BW1 is cut out over a certain length in the engine room, exposing the wires W1 inside. Terminals are connected to the end portions of the wires W1 and are connected to corresponding terminals on the motor 4 side (in actuality, an inverter), although this is similarly not illustrated.

As shown in FIG. 2, a drain portion (this drain portion will be referred to as “main drain portion MD” hereinafter) that has a flat band-shaped form is extended from the base portion of the portion obtained by cutting off the braided member BW1. A ground terminal 7 is connected to the leading end portion of the main drain portion MD.

The ground terminal 7 is formed into a conductive metal plate and is formed integrally from a wire barrel 8 and a fastening portion 9. The wire barrel 8 will be described in detail later. A circular bolt hole 10 is formed in the center of the fastening portion 9, and the ground terminal 7 is fixed by being fastened by a bolt and a nut to a ground point E set at a portion of the body panel that is inside of the engine room.

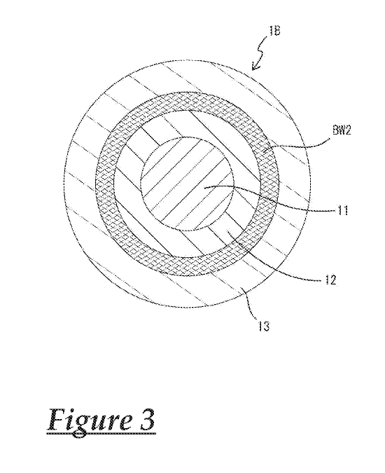

A shield wire (hereinafter referred to as “second shield wire 1B”) that connects the high-voltage battery 2 and the low-voltage battery 5 is a coaxial cable shown in FIG. 3. That is, a core wire 11 is arranged in the center, and the entirety thereof is covered with an internal coating 12. A braided member BW2 surrounds the entire length of the exterior thereof, and an external coating 13 further covers the exterior of the braided member BW2. Note that the braided member BW2 of the second shield wire 1B has the same configuration as the braided member BW1 of the first shield wire 1A.

As shown in FIG. 2, the outer coating 13 of the second shield wire 1B is stripped along a certain length at the end portion on the low-voltage battery 5 side. In the stripped portion, the braided member BW2 is also further stripped, except for a portion. Accordingly, a drain portion D1 extends in the form of a thin cord from the base portion side of the stripped braided member BW2. Hereinafter, the drain portion D1 refers to the battery-side drain portion D1.

At the leading end portion of the portion at which the external coating 13 and the braided member BW2 are stripped and the internal coating 12 is exposed, the internal coating 12 is also stripped and the core wire 11 is exposed. A terminal metal fitting 14 is attached to the exposed core wire 11 and is connected to the low-voltage battery 5 side (in actuality, to a DC/DC converter).

The extended end portion of the battery-side drain portion D1 is connected to a joint terminal J1. The joint terminal J1 is formed using a conducting metallic plate and includes a cylindrical crimped tube 15 with both ends open. The extended end of the battery-side drain portion D1 is inserted into the interior through one opening of the crimped cylinder 15. A core wire portion exposed at one end of a battery-side relay wire L1 is inserted through the opening on the side of the crimped cylinder 15 opposite to the side into which the battery-side drain portion D1 is inserted. The battery-side drain portion D1 and the battery-side relay wire L1 are inserted into the crimped cylinder 15 so as to cross each other in opposite directions and are in a relationship in which portions thereof overlap in the length direction. In this state, the crimped cylinder 15 is crimped, whereby the battery-side relay wire L1 and the battery-side drain portion D1 are electrically connected. In the present embodiment, insulation is ensured due to the crimped cylinder 15 being included and the connected portions of the battery-side relay wire L1 and the battery-side drain portion D1 being sealed by a tape winding 16.

The other end of the battery-side relay wire L1 is inserted into the wire barrel 8 of the ground terminal 7. This will be described once again later.

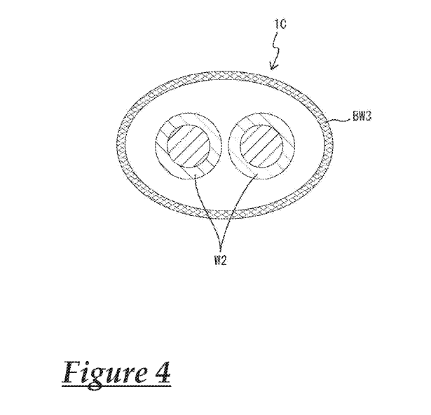

As shown in FIG. 4, the shield wire (hereinafter referred to as “third shield wire 1C”) that connects the electric compressor 3 and the high-voltage battery 2 is of a type in which two wires W2 are collectively surrounded by a braided member BW3. Note that the braided member BW3 also has the same configuration as the braided members BW1 and BW2 in the first and second shield wires 1A and 1B.

As shown in FIG. 2, at the end portion on the electric compressor 3 side of the third shield wire 1C, the braided member BW3 has been stripped over a certain length, except for a portion thereof. As a result, the two wires W2 are exposed, and a drain portion (hereinafter, “compressor-side drain portion D2”) in the form of a thin cord is formed so as to extend from the base of the stripped portion of the braided member BW3. Terminal metal fittings (not shown) are connected to the exposed core wires at the end portions of both of the exposed wires W2, and the end portions are inserted into the cavity of the connector 17. Thus, the shield wire 1C (both wires W2) is connected to the electric compressor 3 through a connector.

The compressor-side drain portion D2 is also connected to one end of the compressor-side relay wire L2 via a joint terminal J2 with an identical configuration, for example, through the same means as the battery-side drain portion D1. The core wires are exposed at the other end of the compressor-side relay wire L2 and are inserted into the wire barrel 8 of the ground terminal 7 along with the core wire of the battery-side relay wire L1.

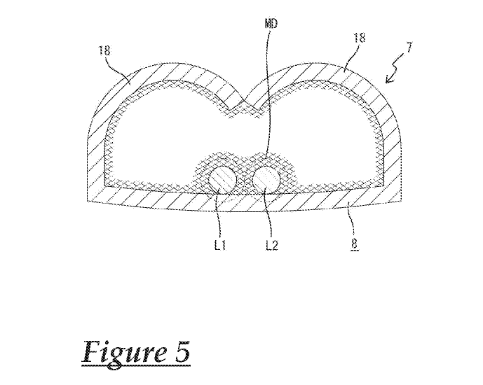

FIG. 5 shows a state in which the main drain portion MD and the two battery-side and compressor-side relay wires L1 and L2 are crimped inside of the wire barrel 8. As shown in FIG. 5, the wire barrel 8 has a pair of barrel pieces 18. The end portions of the two battery-side and compressor-side relay wires L1 and L2 are both stripped, exposing the core wires.

In a state prior to the crimping of the wire barrel 8, in which the two barrel pieces are open, the two core wires are installed on the bottom surface of the wire barrel 8 and are arranged in a state of being parallel to the central portion in the width direction. Also, the core wires are arranged so that the main drain portion MD is placed thereon. In this state, when the leading ends of the two barrel pieces 18 are crimped so as to come into contact with the upper surface of the main drain portion MD, the main drain portion MD causes the surface pressure to act from almost directly above on both the battery-side and compressor-side relay wires. As a result, the battery-side and compressor-side relay wires are pressed to the bottom surface of the wire barrel 8 and are placed with almost no gap in a state of being compressed in the space in the wire barrel 8 along with the main drain portion MD.

To give a description of the effect of the present embodiment configured as described above, the ground terminal 7 is connected to the main drain portion MD extended from the braided member BW1 of the first shield wire, and ground lines (relay wires L1 and L2) of the second and third shield wires 1B and 1C are collectively crimped at the ground terminal 7. Thus, since the grounding of the three shield wires 1A, 1B, and 1C can be grouped together in one ground point E, and the number of installation locations of the ground points E can be reduced in comparison to the case of separately installing the ground points.

Also, in the second and third shield wires 1B and 1C, the drain portions D1 and D2 are extended from the braided members BW2 and BW3 respectively, and are separately connected to the relay wires L1 and L2 via the joint terminals J1 and J2. Accordingly, in comparison to a scheme in which three shield wires and ground wires are bundled together and the exposed portions of the braided members are reliably brought into contact with each other as with the conventional technique, stability is provided to the grounding due to the fact that the electrical connection state of the ground lines of the shield wires 1A, 1B, and 1C are stable and the electrical resistance is also reduced.

Furthermore, the drain portions (including the main drain portion MD) and the relay wires L1 and L2 all have preferable flexibility, and therefore the routing directions of the ground lines can be selected freely.

Moreover, the main drain portion MD and the battery-side and compressor-side relay wires L1 and L2 are connected collectively by the ground terminal 7. In this case, the crimping state in the wire barrel 8 is as shown in FIG. 5, as described above. In other words, the relay wires L1 and L2, which are small-diameter wires, are installed aligned on the bottom surface of the wire barrel 8, the approximately strip-shaped main drain portion MD is placed thereon, and the barrel pieces 18 are crimped. If, in contrast to the present embodiment, the main drain portion MD is arranged on the bottom surface side and the two relay wires L1 and L2 are arranged thereon, the crimping forces applied by the two barrel pieces are less likely to act on the relay wires L1 and L2, and there is a risk that a favorable crimping state will not be obtained. However, if an arrangement such as that shown in the present embodiment is used, the crimping forces at the time of crimping can be applied as surface pressure from the main drain portion MD on the two relay wires L1 and L2, and therefore collective crimping of the main drain portion MD and the two relay wires L1 and L2 can be performed stably. This stabilizes the grounding.

### Other Embodiments

The present invention is not limited to the embodiment described above with reference to the drawings, and for example, the following embodiments are also encompassed in the technical scope of the present invention.

The above-described embodiment described three shield wires 1A, 1B, and 1C, but there is to be no limitation on the number of wires.

In the above-described embodiment, the main drain portion MD is extended from the braided member BW1 of the first shield wire 1A, but the main drain portion MD may be extended from another shield wire.

In the above-described embodiment, the drain portions D1 and D2 and the relay wires L1 and L2 are connected via the joint terminals J1 and J2, but the drain portions D1 and D2 and the relay wires L1 and L2 may be directly connected through a means such as soldering, without using joint terminals.

In the above-described embodiment, a so-called open barrel scheme, in which the wire barrel 8 of the ground terminal 7 is formed using a pair of barrel pieces 18, is given as an example, but there is no limitation to this, and a cylindrical shape with no break in the circumferential direction, or a so-called closed barrel scheme, may be used.

It is to be understood that the foregoing is a description of one or more preferred exemplary embodiments of the invention. The invention is not limited to the particular embodiment(s) disclosed herein, but rather is defined solely by the claims below. Furthermore, the statements contained in the foregoing description relate to particular embodiments and are not to be construed as limitations on the scope of the invention or on the definition of terms used in the claims, except where a term or phrase is expressly defined above. Various other embodiments and various changes and modifications to the disclosed embodiment(s) will become apparent to those skilled in the art. All such other embodiments, changes, and modifications are intended to come within the scope of the appended claims.

As used in this specification and claims, the terms “for example,” “e.g.,” “for instance,” “such as,” and “like,” and the verbs “comprising,” “having,” “including,” and their other verb forms, when used in conjunction with a listing of one or more components or other items, are each to be construed as open-ended, meaning that the listing is not to be considered as excluding other, additional components or items. Other terms are to be construed using their broadest reasonable meaning unless they are used in a context that requires a different interpretation.

### REFERENCE SIGNS LIST

1A First shield wire

1B Second shield wire

1C Third shield wire

7 Ground terminal

8 Wire barrel

18 Barrel piece

BW1 to BW3 Braided member (shield member)

D1 Battery-side drain portion

D2 Compressor-side drain portion

J1, J2 Joint terminal

L1 Battery-side relay wire

L2 Compressor-side relay wire

MD Main drain portion

1. A grounding structure for shield wires, for collectively grounding a plurality of shield wires in which wires are surrounded by shield members, wherein
drain portions are formed by extracting portions of the shield members of the shield wires to the outside, one of the drain portions is used as a main drain portion, and a ground terminal to be connected to a ground point is attached to a leading end of the main drain portion, and
ends on one side of relay wires are connected to the respective remaining drain portions, and the other ends of the relay wires are connected collectively to the ground terminal.

2. The grounding structure for shield wires according to claim 1, wherein the remaining drain portions and the relay wires are respectively connected by being jointly fastened to barrel portions provided on joint terminals.

3. The grounding structure for shield wires according to claim 1, wherein the shield members are braided wires composed of a plurality of metal element wires, the ground terminal is formed by including a wire barrel having a pair of barrel pieces and a fastening portion that is to be fixed to the ground point, and the wire barrel is crimped in a state in which the relay wires are arranged on a bottom surface side thereof and the main drain portion is arranged on a leading end side of the barrel pieces.
